(19) United States
(12) Patent Application Publication
(10) Pub. No.: US 2026/0058429 A1
(43) Pub. Date: Feb. 26, 2026

(54) LASER APPARATUS, LASER SYSTEM, AND METHOD OF MANUFACTURING ELECTRONIC DEVICE

(71) Applicants: Inter-University Research Institute Corporation National Institutes of Natural Sciences, Tokyo (JP); Gigaphoton Inc., Oyama-shi (JP)

(72) Inventors: Ryo YASUHARA, Toki city (JP); Yuki TAMARU, Oyama-shi (JP)

(73) Assignees: Inter-University Research Institute Corporation National Institutes of Natural Sciences, Tokyo (JP); Gigaphoton Inc., Oyama-shi (JP)

(21) Appl. No.: 19/258,705

(22) Filed: Jul. 2, 2025

(30) Foreign Application Priority Data
Aug. 23, 2024 (JP) 2024-143477

(51) Int. Cl. H01S 3/00; G02F 1/355; G02F 1/39; G03F 7/20

(52) U.S. Cl. CPC H01S 3/0057; G02F 1/3551; G02F 1/39; G03F 7/2006; G03F 7/201

(57) ABSTRACT

A laser apparatus includes a first laser light source configured to output a first pulse laser beam having a wavelength of 183 nm or more and 300 nm or less, and a first electro-optic element including a first electro-optic element material that includes either CLBO or LB4 and transmits the first pulse laser beam and a pair of first electrodes disposed on the first electro-optic element material.

### CROSS-REFERENCE TO RELATED APPLICATIONS

The present application claims the benefit of Japanese Patent Application No. 2024-143477, filed on Aug. 23, 2024, the entire contents of which are hereby incorporated by reference.

### BACKGROUND

### 1. Technical Field

The present disclosure relates to a laser apparatus, a laser system, and a method of manufacturing an electronic device.

### 2. Related Art

In recent years, improvement in the resolution of semiconductor exposure apparatuses has been desired as semiconductor integrated circuits become more miniaturized and highly integrated. As a result, the wavelength of light output from an exposure light source is caused to become shorter. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

The KrF excimer laser apparatus and the ArF excimer laser apparatus each have a large spectral line width of about 350 pm to 400 pm in natural oscillation light. Therefore, when a projection lens is formed by a material that transmits ultraviolet light such as a KrF laser beam and an ArF laser beam, chromatic aberration may occur. As a result, the resolution may decrease. Thus, the spectral line width of the laser beam output from the gas laser apparatus needs to be narrowed to the extent that the chromatic aberration can be ignored. Therefore, a line narrowing module (LNM) including a line narrowing element (an etalon, a grating, and the like) may be provided in a laser resonator of the gas laser apparatus in order to narrow the spectral line width. The gas laser apparatus in which the spectral line width is narrowed is referred to as a line narrowing gas laser apparatus.

### LIST OF DOCUMENTS

### Patent Documents

Patent Document 1: Japanese Patent Laid-Open No. 2006-253571
Patent Document 2: U.S. Patent Application Publication No. 2009/245301
Patent Document 3: U.S. Patent Application Publication No. 2008/112030

### SUMMARY

A laser apparatus according to an aspect of the present disclosure may include a first laser light source and a first electro-optic element. The first laser light source may be configured to output a first pulse laser beam having a wavelength of 183 nm or more and 300 nm or less. The first electro-optic element may include a first electro-optic element material that includes either CLBO or LB4 and transmits the first pulse laser beam, and a pair of first electrodes disposed on the first electro-optic element material.

A laser system according to an aspect of the present disclosure may include a first laser light source, a second laser light source, a beam combiner, and a processor. The first laser light source may be configured to output a first pulse laser beam that has a first polarization direction and has a wavelength of 183 nm or more and 300 nm or less. The second laser light source may be configured to output a second pulse laser beam that has a second polarization direction orthogonal to the first polarization direction and has a wavelength of 183 nm or more and 300 nm or less. The beam combiner may include a first polarizer, a first electro-optic element, and a first drive power supply. The first polarizer may be configured to combine the first pulse laser beam and the second pulse laser beam and propagate the first pulse laser beam and the second pulse laser beam in the same direction by reflecting one of the first pulse laser beam and the second pulse laser beam and transmitting the other of the first pulse laser beam and the second pulse laser beam. The first electro-optic element may include a first electro-optic element material that includes either CLBO or LB4 and transmits the first pulse laser beam and the second pulse laser beam, and a pair of first electrodes disposed on the first electro-optic element material. The first drive power supply may be configured to apply, to the first electrodes, first voltage that is half-wavelength voltage of the first electro-optic element material. The processor may be configured to control the first laser light source and the second laser light source such that the first pulse laser beam and the second pulse laser beam are alternately output, and control the first drive power supply such that a polarization direction of one of the first pulse laser beam and the second pulse laser beam is rotated to be the same as a polarization direction of the other of the first pulse laser beam and the second pulse laser beam.

A method of manufacturing an electronic device according to an aspect of the present disclosure may include generating a first pulse laser beam and a second pulse laser beam with a laser system, outputting the first pulse laser beam and the second pulse laser beam to an exposure apparatus, and exposing a photosensitive substrate to the first pulse laser beam and the second pulse laser beam within the exposure apparatus to manufacture the electronic device. The laser system may include a first laser light source, a second laser light source, a beam combiner, and a processor. The first laser light source may be configured to output a first pulse laser beam that has a first polarization direction and has a wavelength of 183 nm or more and 300 nm or less. The second laser light source may be configured to output a second pulse laser beam that has a second polarization direction orthogonal to the first polarization direction and has a wavelength of 183 nm or more and 300 nm or less. The beam combiner may include a first polarizer, a first electro-optic element, and a first drive power supply. The first polarizer may be configured to combine the first pulse laser beam and the second pulse laser beam and propagate the first pulse laser beam and the second pulse laser beam in the same direction by reflecting one of the first pulse laser beam and the second pulse laser beam and transmitting the other of the first pulse laser beam and the second pulse laser beam. The first electro-optic element may include a first electro-optic element material that includes either CLBO or LB4 and transmits the first pulse laser beam and the second pulse laser beam, and a pair of first electrodes disposed on the first electro-optic element material. The first drive power supply may be configured to apply, to the first electrodes, first voltage that is half-wavelength voltage of the first electro-optic element material. The processor may be configured to control the first laser light source and the second laser light source such that the first pulse laser beam and the second pulse laser beam are alternately output, and control the first drive power supply such that a polarization direction of one of the first pulse laser beam and the second pulse laser beam is rotated to be the same as a polarization direction of the other of the first pulse laser beam and the second pulse laser beam.

### BRIEF DESCRIPTION OF THE DRAWINGS

Some embodiments of the present disclosure will be described below merely as examples with reference to the accompanying drawings.

FIG. 1 shows a configuration of a laser system in a comparative example.

FIG. 2 shows a configuration of a laser apparatus according to a first embodiment.

FIG. 3 shows a surface of a first electro-optic element on which a first pulse laser beam is incident in the first embodiment.

FIG. 4 shows the transmission spectrum of CLBO.

FIG. 5 shows a configuration of a laser apparatus according to a second embodiment.

FIG. 6 shows the configuration of the laser apparatus according to the second embodiment.

FIG. 7 shows the transmission spectrum of LB4.

FIG. 8 shows a configuration of a laser system according to a third embodiment.

FIG. 9 is a timing chart of the third embodiment.

FIG. 10 shows a configuration of a laser system according to a fourth embodiment.

FIG. 11 shows a configuration of a laser system according to a fifth embodiment.

FIG. 12 is a timing chart of the fifth embodiment.

FIG. 13 shows a configuration of an exposure system.

### DESCRIPTION OF EMBODIMENTS

### <Contents>

1. Comparative Example
2. Problem of Comparative Example
3. Electro-optic Element EO1 Including CLBO
   3.1 Configuration
   3.2 Effects
4. Electro-optic Element EO1 Including LB4
   4.1 Configuration
   4.2 Effects
5. Laser System 100c that Increases Output of Pulse Laser Beams by Combining Pulse Laser Beams
   5.1 Configuration
   5.2 Operation
   5.3 Range of Half-wavelength Voltage
   5.4 Effects
6. Laser System 100d in which First Laser Source LS1 Includes Polarization Rotation Element ROT
   6.1 Configuration
   6.2 Effects
7. Laser System 100e with Shared Oscillator
   7.1 Configuration
   7.2 Operation
   7.3 Effects
8. Other
   8.1 Method of Manufacturing Electronic Device
   8.2 Supplementary

Hereinafter, embodiments of the present disclosure will be described in detail with reference to the drawings. The embodiments described below show some examples of the present disclosure and do not limit the contents of the present disclosure. All configurations and operations described in the embodiments are not necessarily essential as configurations and operations of the present disclosure. The same components are denoted by the same reference characters, and redundant descriptions thereof are omitted.

### 1. Comparative Example

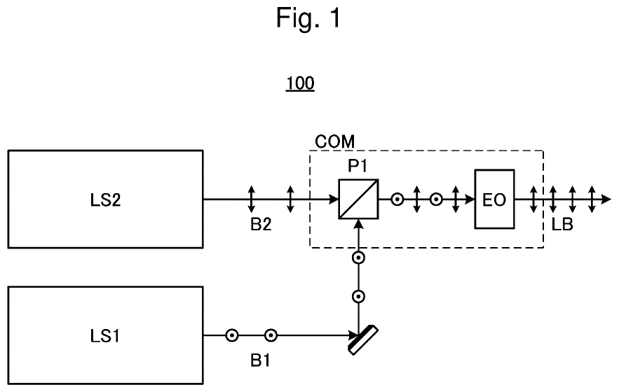

FIG. 1 shows a configuration of a laser system 100 in a comparative example. The comparative example of the present disclosure is an example recognized by the applicant as known only by the applicant and is not a publicly known example admitted by the applicant.

The laser system 100 includes a first laser light source LS1, a second laser light source LS2, and a beam combiner COM. The first laser light source LS1 and the second laser light source LS2 alternately output a first pulse laser beam B1 and a second pulse laser beam B2, respectively. The first pulse laser beam B1 and the second pulse laser beam B2 have polarization directions perpendicular to each other.

The beam combiner COM is disposed in a space including optical paths of both the first pulse laser beam B1 and the second pulse laser beam B2. The beam combiner COM includes a first polarizer P1 and an electro-optic element EO. The first polarizer P1 combines the first pulse laser beam B1 and the second pulse laser beam B2 and propagates the first pulse laser beam B1 and the second pulse laser beam B2 in the same direction by reflecting one of the first pulse laser beam B1 and the second pulse laser beam B2 and transmitting the other of the first pulse laser beam B1 and the second pulse laser beam B2. The electro-optic element EO is configured to be switchable between a first state in which the pulse laser beam is transmitted with the polarization direction being changed and a second state in which the pulse laser beam is directly transmitted without a change in the polarization direction in accordance with phase modulation of the pulse laser beam. The electro-optic element EO outputs the first pulse laser beam B1 and the second pulse laser beam B2 as a laser beam LB while aligning the polarization directions in the same direction.

### 2. Problem of Comparative Example

As exemplified in the comparative example, the electro-optic element EO may be used in the laser system 100. The electro-optic element EO is an element including a material that exhibits an electro-optic effect in which the index ellipsoid changes when voltage is applied. The electro-optic element EO is used for intensity modulation, deflection modulation, and the like of a pulse laser beam in addition to phase modulation of a pulse laser beam.

For example, deuterated potassium dihydrogen phosphate (DKDP) that is a material that exhibits an electro-optic effect may be used to transmit a pulse laser beam at a wavelength of ultraviolet light. However, the internal transmittance per unit length (mm) becomes 50% or less at a wavelength of 300 nm or less. When the oscillation wavelength of a KrF excimer laser apparatus and the oscillation wavelength of an ArF excimer laser apparatus are reached, the internal transmittance is further lowered. At present, there are few reports on the electro-optic coefficient of materials that are transparent particularly at the wavelength of 300 nm or less. The inventors have measured the electro-optic coefficients of materials, which are transparent at the wavelength of 300 nm or less, at the wavelength of 193 nm by the Senarmont method, and conducted a search for materials.

Embodiments described below relate to using, together with a laser light source, an electro-optic element including a material that has a sufficient internal transmittance and a sufficient electro-optic coefficient even at a wavelength of 300 nm or less.

### 3. Electro-optic Element EO1 Including CLBO

### 3.1 Configuration

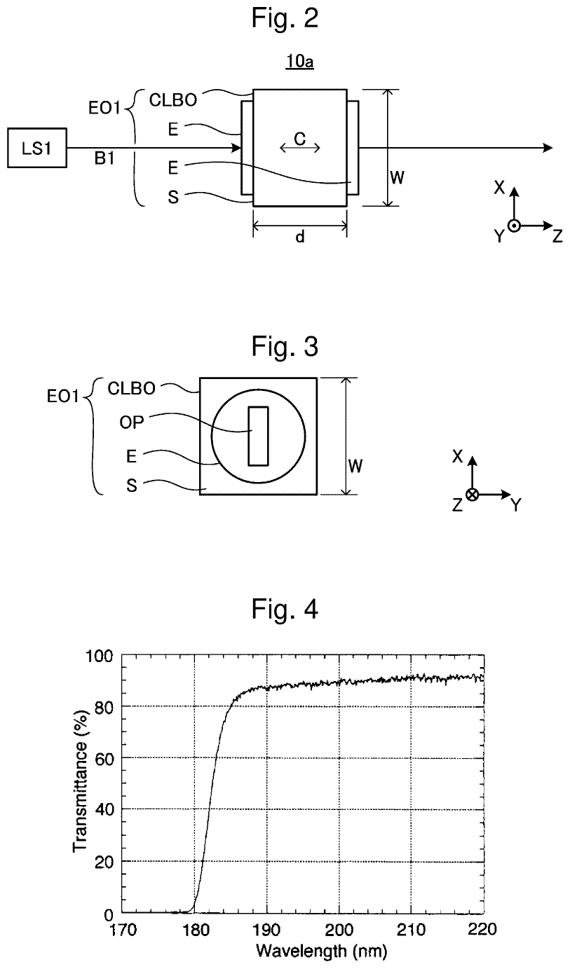

FIG. 2 shows a configuration of a laser apparatus 10a according to a first embodiment. The laser apparatus 10a includes a first laser light source LS1 and a first electro-optic element EO1. The first laser light source LS1 is configured to output the first pulse laser beam B1 having a wavelength λ of 183 nm or more and 300 nm or less. The first laser light source LS1 is a KrF excimer laser apparatus or an ArF excimer laser apparatus, for example. The pulse laser beam output from the KrF excimer laser apparatus and the ArF excimer laser apparatus has a rectangular beam cross-section.

The first electro-optic element EO1 includes a crystal of cesium lithium borate (CLBO, CsLiB₆O₁₀) that transmits the first pulse laser beam B1, and a pair of first electrodes E. Here, CLBO is one example of a first electro-optic element material in the present disclosure. In the following description, the term “first electro-optic element material” includes either CLBO or LB4 described below. The c-axis of CLBO is shown in FIG. 2 by reference character C. The first electrodes E are disposed on two surfaces of CLBO that face each other in the c-axis direction.

The transmission direction of the first pulse laser beam B1 and the direction of application of the voltage by the first electrodes E are both the c-axis direction of CLBO. It is desirable that a length d of CLBO in the c-axis direction be 0.7 times or more and 1.0 times or less of a length W of the long side of a surface S of CLBO on which the first pulse laser beam B1 is incident. When the surface S is circular, the length W of the long side is the diameter of the surface S. A specific numerical value of the length d is preferably 5 mm or more and 20 mm or less.

FIG. 3 shows a surface of the first electro-optic element EO1 on which the first pulse laser beam B1 is incident in the first embodiment. FIG. 3 corresponds to a view of the first electro-optic element EO1 seen from the left side in FIG. 2. A surface of the first electro-optic element EO1 from which the first pulse laser beam B1 is output, that is, a view of the first electro-optic element EO1 seen from the right side in FIG. 2 is similar to FIG. 3. Each of the first electrodes E has a slit-shaped opening OP through which the first pulse laser beam B1 passes. The opening OP may be rectangular. The external shape of the first electrode E may be circular or quadrilateral.

FIG. 4 shows the transmission spectrum of CLBO. The reference source is Yusuke Mori, Takatomo Sasaki, “New nonlinear optical crystal: cesium lithium borate”, Journal of the Japanese Association for Crystal Growth, Japanese Association for Crystal Growth, September 1995, Vol. 22, No. 4, and p 310-317. Here, CLBO has an internal transmittance of 50% or more per unit length (mm) in a wavelength range of 183 nm or more, and has an internal transmittance of 80% or more from 185 nm to the infrared wavelength range. The measurement result of an electro-optic coefficient r₆₃ of CLBO measured by the inventors has been 2.1 pm/V.

### 3.2 Effects

According to the first embodiment, the laser apparatus 10a includes the first laser light source LS1 and the first electro-optic element EO1. The first laser light source LS1 is configured to output the first pulse laser beam B1 having the wavelength λ of 183 nm or more and 300 nm or less. The first electro-optic element EO1 includes the first electro-optic element material that includes CLBO and transmits the first pulse laser beam B1, and the pair of first electrodes E disposed on the first electro-optic element material.

According to the above, CLBO has a high electro-optic coefficient and also has a high internal transmittance for ultraviolet light having a wavelength of 183 nm or more and 300 nm or less. Therefore, it becomes possible to effectively modulate the first pulse laser beam B1.

According to the first embodiment, the first electro-optic element material includes CLBO, the transmission direction of the first pulse laser beam B1 and the direction of application of the voltage by the first electrodes E are both the c-axis direction of CLBO, and the length d in the c-axis direction is 0.7 times or more and 1.0 times or less of the length W of the long side of the surface S of CLBO on which the first pulse laser beam B1 is incident. According to the first embodiment, the length d in the c-axis direction 5 mm or more and 20 mm or less.

According to the above, a high electro-optic effect can be exhibited by causing the direction of application of the voltage and the transmission direction of the first pulse laser beam B1 to be the same. A dielectric breakdown can be suppressed by causing the length d in the c-axis direction that is the direction of application of the voltage to be sufficiently long. A decrease in the energy of the transmitted light can be suppressed by not making the length d in the c-axis direction that is the transmission direction of the first pulse laser beam B1 excessively long.

According to the first embodiment, the first electro-optic element material includes CLBO, and each of the first electrodes E has a slit-shaped opening OP through which the first pulse laser beam B1 passes.

According to the above, a high electro-optic effect can be exhibited by disposing CLBO such that the first pulse laser beam B1 passes through the opening OP of each of the first electrodes E. By causing the opening OP to be slit-shaped, the passage of the first pulse laser beam B1 having a rectangular beam cross-section can be realized. Meanwhile, area of the opening OP can be reduced, and hence the uniformity of the electric field in CLBO can be ensured.

### 4. Electro-optic Element EO1 Including LB4

### 4.1 Configuration

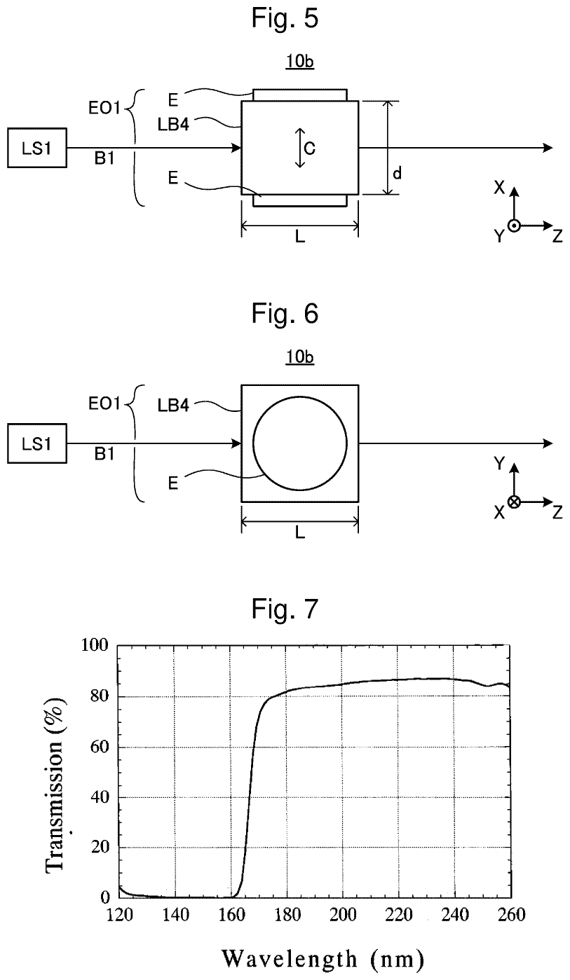

FIG. 5 and FIG. 6 show configurations of a laser apparatus 10b according to a second embodiment. FIG. 6 corresponds to a view of the laser apparatus 10b seen from the lower side in FIG. 5. A view of the laser apparatus 10b seen from the upper side in FIG. 5 is similar to FIG. 6. The laser apparatus 10b includes the first laser light source LS1 and the first electro-optic element EO1. The first laser light source LS1 is similar to that described in the first embodiment.

The first electro-optic element EO1 includes a crystal of lithium tetraborate (LB4, Li₂B₄O₇) that transmits the first pulse laser beam B1, and the pair of first electrodes E. Here, LB4 is one example of the first electro-optic element material in the present disclosure. The c-axis of LB4 is shown in FIG. 5 by reference character C. The first electrodes E are disposed on two surfaces of LB4 that face each other in the c-axis direction.

The direction of application of the voltage by the first electrodes E is the c-axis direction of LB4. Meanwhile, the transmission direction of the first pulse laser beam B1 is a direction perpendicular to the c-axis direction of LB4. The term “vertical” as used herein is not limited to a case of being perfectly vertical and includes a case in which there is a deviation within 5°. The length d of LB4 in the c-axis direction is preferably 2 mm or more and 6 mm or less. A length L of LB4 in the transmission direction of the first pulse laser beam B1 is preferably 10 mm or more and 30 mm or less. When the length L is increased, the energy of the transmitted light is reduced. However, when d/L is reduced, there is an effect of reducing the half-wavelength voltage as described later. The first pulse laser beam B1 does not necessarily need to pass through the first electrodes E, and hence the first electrodes E do not necessarily need to have the openings OP as in the first embodiment, and the uniformity of the electric field in LB4 can be easily ensured.

FIG. 7 shows the transmission spectrum of LB4. The reference source is R. Komatsu, T. Sugawara, K. Sassa, N. Sarukura, Z. Liu, S. Izumida, Y. Segawa, S. Uda, T. Fukuda, K. Yamanouchi; Growth and ultraviolet application of Li₂B₄O₇ crystals: Generation of the fourth and fifth harmonics of Nd:Y₃Al₅O₁₂: lasers. Appl. Phys. Lett. 30 Jun. 1997; 70 (26): 3492-3494. Here, LB4 has an internal transmittance of 50% or more per unit length (mm) in a wavelength range of 163 nm or more, and has an internal transmittance of 80% or more from 175 nm to the infrared wavelength range. The measurement result of an electro-optic coefficient r_{c} of LB4 measured by the inventors has been 0.3 pm/V.

### 4.2 Effects

According to the second embodiment, the first electro-optic element material includes LB4, the transmission direction of the first pulse laser beam B1 is perpendicular to the c-axis direction of LB4, the direction of application of the voltage by the first electrodes E is the c-axis direction, and the length d of the c-axis direction 2 mm or more and 6 mm or less.

According to the above, LB4 has a high electro-optic coefficient and also has a high internal transmittance for ultraviolet light having a wavelength of 183 nm or more and 300 nm or less. Therefore, it becomes possible to effectively modulate the first pulse laser beam B1. The electro-optic effect can be enhanced by disposing LB4 such that the first pulse laser beam B1 is transmitted in a manner that is perpendicular to the c-axis direction. A dielectric breakdown can be suppressed by making the length d in the c-axis direction that is the direction of application of the voltage sufficiently long. The half-wavelength voltage can be reduced by not making the length d excessively long.

According to the second embodiment, the length L of LB4 in the transmission direction of the first pulse laser beam B1 is 10 mm or more and 30 mm or less.

According to the above, the half-wavelength voltage can be reduced by making the length L of the first pulse laser beam B1 in the transmission direction sufficiently long. A decrease in energy of the transmitted light can be suppressed by not making the length L excessively long.

### 5. Laser System 100c that Increases Output of Pulse Laser Beams by Combining Pulse Laser Beams

### 5.1 Configuration

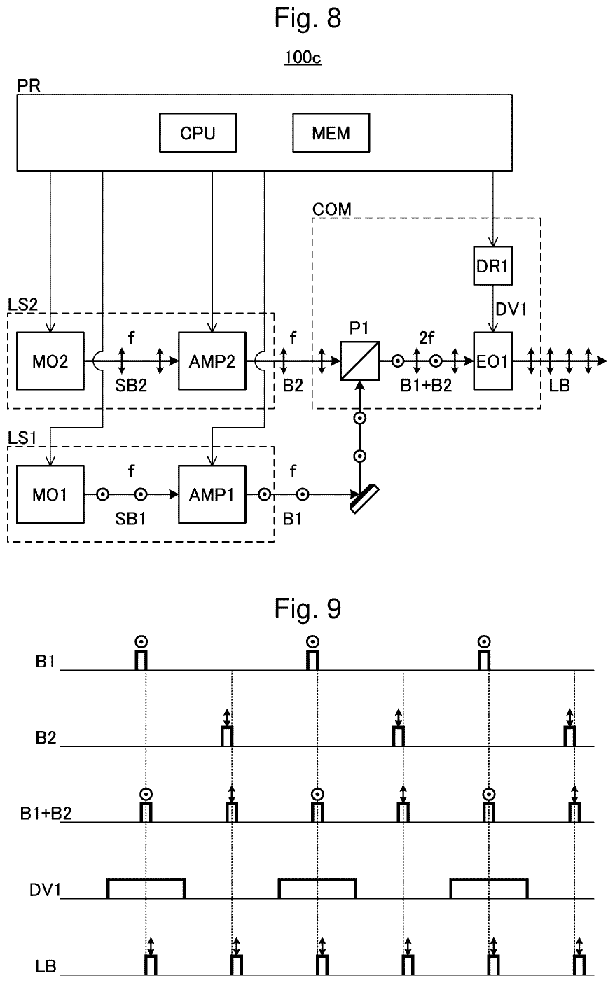

FIG. 8 shows a configuration of a laser system 100c according to a third embodiment of the present invention. The laser system 100c includes the first laser light source LS1, the second laser light source LS2, the beam combiner COM, and a processor PR. The first laser light source LS1 is configured to output the first pulse laser beam B1 having the wavelength \ of 183 nm or more and 300 nm or less, and the second laser light source LS2 is configured to output the second pulse laser beam B2 having the wavelength λ of 183 nm or more and 300 nm or less. As one example, the first laser source LS1 includes a first oscillator MO1 and a first amplifier AMP1. As one example, the second laser source LS2 includes a second oscillator MO2 and a second amplifier AMP2.

Each of the first oscillator MO1 and the second oscillator MO2 is configured by a KrF excimer laser apparatus or an ArF excimer laser apparatus, for example. Alternatively, each of the first oscillator MO1 and the second oscillator MO2 may be configured by a solid-state laser. The first oscillator MO1 and the second oscillator MO2 respectively output first seed light SB1 and second seed light SB2 each having the wavelength λ of 183 nm or more and 300 nm or less. The first seed light SB1 has a first polarization direction, and the second seed light SB2 has a second polarization direction. The first polarization direction and the second polarization direction are orthogonal to each other.

Each of the first amplifier AMP1 and the second amplifier AMP2 is configured by a KrF excimer laser apparatus or an ArF excimer laser apparatus, for example. The first amplifier AMP1 and the second amplifier AMP2 are disposed in optical paths of the first seed beam SB1 and the second seed beam SB2, respectively. The first amplifier AMP1 and the second amplifier AMP2 amplify the first seed beam SB1 and the second seed beam SB2 and output the first pulse laser beam B1 and the second pulse laser beam B2, respectively. The first pulse laser beam B1 has the first polarization direction, and the second pulse laser beam B2 has the second polarization direction. Optical qualities such as the beam size and the beam divergence of the first pulse laser beam B1 and the second pulse laser beam B2 are equivalent to each other.

The beam combiner COM is disposed in a space including the optical paths of both the first pulse laser beam B1 and the second pulse laser beam B2. The beam combiner COM includes the first polarizer P1, the first electro-optic element EO1, and a first drive power supply DR1.

The first polarizer P1 is similar to that described in the comparative example.

The configuration of the first electro-optic element EO1 is similar to that of the first electro-optic element EO1 in the first embodiment or the second embodiment. In the third embodiment, the first electro-optic element EO1 transmits the first pulse laser beam B1 and the second pulse laser beam B2 and outputs the first pulse laser beam B1 and the second pulse laser beam B2 as the laser beam LB while aligning the polarization directions of the first pulse laser beam B1 and the second pulse laser beam B2 in the same direction.

The first drive power supply DR1 applies, to the first electrodes E of the first electro-optic element EO1 (see FIGS. 2 and 5), first voltage DV1 that is half-wavelength voltage of the first electro-optic element material. The half-wavelength voltage is voltage at which the change in the phase difference between an ordinary ray and an extraordinary ray is 180°.

The processor PR is a processor including a memory MEM in which a control program is stored, and a central processing unit (CPU) that executes the control program. The processor PR is specially configured or programmed to execute various processes included in the present disclosure.

### 5.2 Operation

FIG. 9 is a timing chart of the third embodiment. Broken lines in the up-down direction in FIG. 9 indicate that events indicated in the positions of each broken line occur at the same time. One pulse of the first pulse laser beam B1 or the second pulse laser beam B2 and one pulse of the laser beam LB resulting from this pulse have a slight time difference in accordance with the optical path lengths in the laser system 100c, but are approximately aligned on the same broken line.

The processor PR sets the charging voltage of each of the first oscillator MO1 and the second oscillator MO2 and controls the pulse energy of the first seed light SB1 and the second seed light SB2. The processor PR transmits a trigger signal to each of the first oscillator MO1 and the second oscillator MO2 and controls the oscillation timings of the first oscillator MO1 and the second oscillator MO2 such that the first seed light SB1 and the second seed light SB2 are alternately output. A repetition frequency f of each of the first seed light SB1 and the second seed light SB2 is 6 kHz, for example. A difference in the oscillation timing between the first seed light SB1 and the second seed light SB2 is 1/(2f) second, for example.

The processor PR sets the charging voltage of each of the first amplifier AMP1 and the second amplifier AMP2 and controls the pulse energy of the first pulse laser beam B1 and the second pulse laser beam B2. The processor PR transmits a trigger signal to each of the first amplifier AMP1 and the second amplifier AMP2 and controls the excitation timings such that a laser medium is excited at a timing at which the first seed light SB1 and the second seed light SB2 enter the first amplifier AMP1 and the second amplifier AMP2, respectively. The first pulse laser beam B1 and the second pulse laser beam B2 are alternately output. The difference in the repetition frequency f and the output timing between the first pulse laser beam B1 and the second pulse laser beam B2 is similar to the difference in the repetition frequency f and the oscillation timing between the first seed light SB1 and the second seed light SB2.

In the beam combiner COM, the first polarizer P1 reflects the first pulse laser beam B1 having the first polarization direction and transmits the second pulse laser beam B2 having the second polarization direction, to thereby combine the first pulse laser beam B1 and the second pulse laser beam B2 and propagate the first pulse laser beam B1 and the second pulse laser beam B2 in the same direction. The repetition frequency of the first pulse laser beam and the second pulse laser beam B1+B2 output from the first polarizer P1 is 2f that is twice the repetition frequency f and is 12 kHz, for example.

Although a case in which the first pulse laser beam B1 is S-polarized light with respect to the first polarizer P1 and the second pulse laser beam B2 is P-polarized light with respect to the first polarizer P1 has been shown, the relationship between the S-polarized light and the P-polarized light may be reversed. In other words, the first polarizer P1 may transmit the first pulse laser beam B1 and reflect the second pulse laser beam B2.

The processor PR controls the first drive power supply DR1 such that the first voltage DV1 is applied to the first electrodes E at a timing at which the first pulse laser beam B1 having the first polarization direction among the first pulse laser beam and the second pulse laser beam B1+B2 output from the first polarizer P1 passes through the first electro-optic element EO1. The first electro-optic element EO1 transmits the pulse laser beam by rotating the polarization direction of the pulse laser beam by 90° while the first voltage DV1 is applied to the first electrodes E, and directly transmits the pulse laser beam without changing the polarization direction of the pulse laser beam while the first voltage DV1 is not applied to the first electrodes E. As a result, the polarization direction of the first pulse laser beam B1 is rotated and becomes the same polarization direction as the polarization direction of the second pulse laser beam B2. The first electro-optic element EO1 outputs the laser beam LB including the second pulse laser beam B2 having the second polarization direction and the first pulse laser beam B1 of which polarization direction has been changed to the second polarization direction.

Although a case in which the polarization direction of the first pulse laser beam B1 is changed has been shown, the polarization direction of the second pulse laser beam B2 may be changed without changing the polarization direction of the first pulse laser beam B1. In other words, the first electro-optic element EO1 may output the laser beam LB having the first polarization direction.

As described above, the first electro-optic element EO1 sets the polarization directions of the first pulse laser beam B1 and the second pulse laser beam B2 to be the same. The expression of “the polarization directions are the same” means that the angle difference between the polarization directions is within 5°.

### 5.3 Range of Half-wavelength Voltage

The refractive index of the ordinary ray in the first electro-optic element material is represented by nₒ. When the first electro-optic material is CLBO, a half-wave voltage V_{λ/2} is given by the following expression.

V_{λ/2}=λd/(2nₒ³r_{c}L)

Here, when the wavelength λ is 183 nm or more and 300 nm or less, the half-wavelength voltage V_{λ/2} of CLBO becomes 8 kV or more and 12 kV or less.

When the first electro-optic element material is LB4, the half-wave voltage V_{λ/2} is given by the following expression.

V_{λ/2}=λd/(2nₒ³r_{c}L)

Here, when the wavelength λ is set to be 183 nm or more and 300 nm or less and the length d of LB4 in the c-axis direction and the length L of LB4 in the transmission direction of the first pulse laser beam B1 are set to be within the range described in the second embodiment, the half-wavelength voltage V_{λ/2} of LB4 becomes 4 kV or more and 41 kV or less. However, it is desirable to simplify the insulation configuration of the apparatus by setting d/L such that the half-wavelength voltage V_{λ/2} becomes 15 kV or less.

### 5.4 Effects

According to the third embodiment, the laser system 100c includes the first laser light source LS1, the second laser light source LS2, the beam combiner COM, and the processor PR. The first laser light source LS1 is configured to output the first pulse laser beam B1 having the first polarization direction and having the wavelength λ of 183 nm or more and 300 nm or less. The second laser light source LS2 is configured to output the second pulse laser beam B2 having the second polarization direction orthogonal to the first polarization direction and having the wavelength λ of 183 nm or more and 300 nm or less. The beam combiner COM includes the first polarizer P1, the first electro-optic element EO1, and the first drive power supply DR1. The first polarizer P1 is configured to combine the first pulse laser beam B1 and the second pulse laser beam B2 and propagate the first pulse laser beam B1 and the second pulse laser beam B2 in the same direction by reflecting one of the first pulse laser beam B1 and the second pulse laser beam B2 and transmitting the other of the first pulse laser beam B1 and the second pulse laser beam B2. The first electro-optic element EO1 includes the first electro-optic element material that includes either CLBO or LB4 and that transmits the first pulse laser beam B1 and the second pulse laser beam B2, and the pair of first electrodes E disposed on the first electro-optic element material. The first drive power supply DR1 is configured to apply, to the first electrodes E, the first voltage DV1 that is half-wavelength voltage of the first electro-optic element material. The processor PR is configured to control the first laser light source LS1 and the second laser light source LS2 such that the first pulse laser beam B1 and the second pulse laser beam B2 are alternately output, and control the first drive power supply DR1 such that the polarization direction of one of the first pulse laser beam B1 and the second pulse laser beam B2 is rotated to be the same as the polarization direction of the other of the first pulse laser beam B1 and the second pulse laser beam B2.

According to the above, the load on the first laser light source LS1 and the second laser light source LS2 can be suppressed, the deterioration of the optical components can be suppressed, and the laser output can be improved by combining the first pulse laser beam B1 and the second pulse laser beam B2 by alternately outputting the first pulse laser beam B1 and the second pulse laser beam B2. By using CLBO or LB4, it becomes possible to suppress the decrease in the laser power due to the synthesis even in the case of ultraviolet light having the wavelength λ of 183 nm or more and 300 nm or less. By causing the output directions of the first pulse laser beam B1 and the second pulse laser beam B2 to be the same and the polarization direction to be the same, practical use in an exposure apparatus or the like is enabled.

According to the third embodiment, the first laser light source LS1 includes the first oscillator MO1 configured to output the first seed light SB1 having the first polarization direction and having the wavelength λ of 183 nm or more and 300 nm or less, and the first amplifier AMP1 configured to amplify the first seed light SB1 and output the first pulse laser beam B1. The second laser light source LS2 includes the second oscillator MO2 configured to output the second seed light SB2 having the second polarization direction and having the wavelength λ of 183 nm or more and 300 nm or less, and the second amplifier AMP2 configured to amplify the second seed light SB2 and output the second pulse laser beam B2.

According to the above, the first seed light SB1 and the second seed light SB2 are amplified by the first amplifier AMP1 and the second amplifier AMP2, respectively, and then combined. As a result, the repetition frequency of the combined laser beam LB can be increased without increasing the repetition frequencies of the first oscillator MO1 and the second oscillator MO2 and the first amplifier AMP1 and the second amplifier AMP2.

According to the third embodiment, the first electro-optic element material includes CLBO, and the half-wavelength voltage V_{λ/2} is 8 kV or more and 12 kV or less.

According to the above, when the wavelength ranges of the first pulse laser beam B1 and the second pulse laser beam B2 are set to be 183 nm or more and 300 nm or less, the half-wavelength voltage V_{λ/2} can be appropriately set.

According to the third embodiment, the first electro-optic element material includes LB4, and the half-wavelength voltage V_{λ/2} is 4 kV or more and 41 kV or less.

According to the above, the wavelength ranges of the first pulse laser beam B1 and the second pulse laser beam B2 can be set to be 183 nm or more and 300 nm or less, and the half-wavelength voltage V_{λ/2} can be set appropriately when LB4 is set to an appropriate range.

According to the third embodiment, the first electro-optic element material includes LB4, and the half-wavelength voltage V_{λ/2} is 4 kV or more and 15 kV or less.

According to the above, it becomes possible to simplify the first drive power supply DR1 and an insulation structure of wiring from the first drive power supply DR1 to the first electro-optic element EO1.

### 6. Laser System 100d in which First Laser Source LS1 Includes Polarization Rotation Element ROT

### 6.1 Configuration

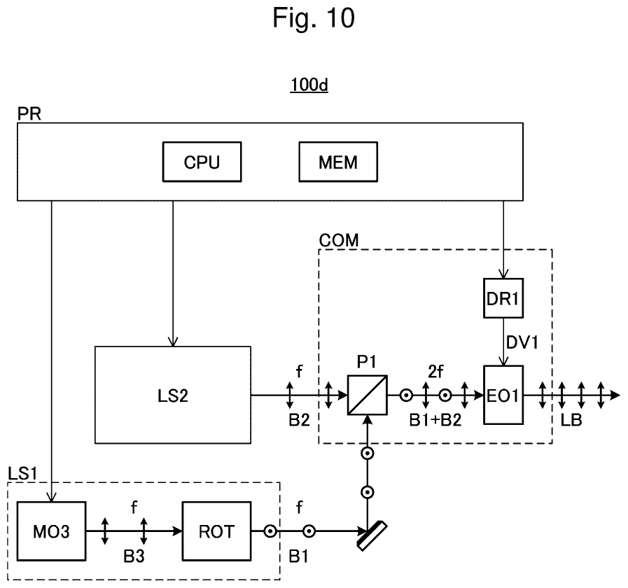

FIG. 10 shows a configuration of a laser system 100d according to a fourth embodiment. The laser system 100d differs from the third embodiment in that the first laser light source LS1 includes a third oscillator MO3 and a polarization rotation element ROT instead of the first oscillator MO1. In addition to the configuration of FIG. 10, the first laser source LS1 may further include the first amplifier AMP1 as in the third embodiment. The second laser light source LS2, the beam combiner COM, and the processor PR may be similar to those described in the third embodiment.

While the first oscillator MO1 outputs the first seed light SB1 having the first polarization direction, the third oscillator MO3 outputs a third pulse laser beam B3 having the second polarization direction. Regarding other features, the third oscillator MO3 is similar to the first oscillator MO1.

The polarization rotation element ROT includes an electro-optic element, a half-wave plate, or a Faraday rotator, for example. The polarization rotation element ROT rotates the polarization direction of the third pulse laser beam B3 and outputs the third pulse laser beam B3 as the first pulse laser beam B1 having the first polarization direction.

### 6.2 Effects

According to the fourth embodiment, the first laser light source LS1 includes the third oscillator MO3 configured to output the third pulse laser beam B3 having the second polarization direction and having the wavelength λ of 183 nm or more and 300 nm or less, and the polarization rotation element ROT configured to rotate the polarization direction of the third pulse laser beam B3 to make the third pulse laser beam B3 the first pulse laser beam B1 having the first polarization direction.

According to the above, both the second laser light source LS2 and the third oscillator MO3 output the pulse laser beam having the second polarization direction. Therefore, similar apparatus configurations can be adopted, and the procurement cost of the apparatuses can be reduced.

Regarding other features, the fourth embodiment is similar to the third embodiment.

### 7. Laser System 100e with Shared Oscillator

### 7.1 Configuration

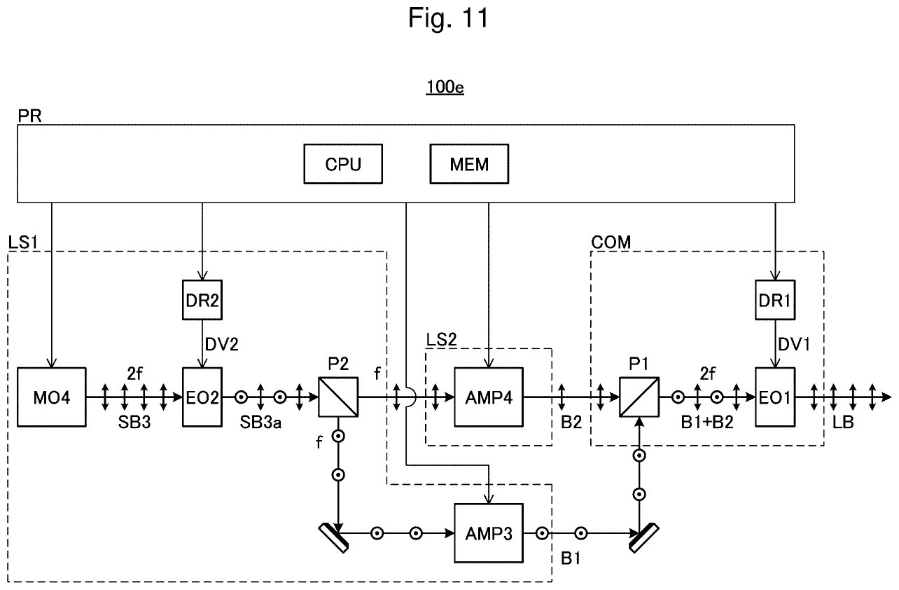

FIG. 11 shows a configuration of a laser system 100e according to a fifth embodiment. In the laser system 100e, the first laser light source LS1 and the second laser light source LS2 are different from those described in the third embodiment. The beam combiner COM and the processor PR may be similar to those described in the third embodiment.

In the laser system 100e, the first laser light source LS1 includes a fourth oscillator MO4, a second electro-optic element EO2, a second drive power supply DR2, a second polarizer P2, and a third amplifier AMP3.

The fourth oscillator MO4 outputs third seed light SB3 having the second polarization direction. The repetition frequency of the third seed light SB3 is 2f. Even when the repetition frequency of the third seed light SB3 is high, the pulse energy prior to being amplified by an amplifier is low, and hence the deterioration of optical components can be suppressed. Regarding other features, the fourth oscillator MO4 is similar to the first oscillator MO1.

The second electro-optic element EO2 is arranged in an optical path of the third seed light SB3. The second electro-optic element EO2 has a configuration similar to that of the first electro-optic element EO1, but differs from the first electro-optic element EO1 in that the polarization direction of some pulses out of the pulses included in the third seed light SB3 having the second polarization direction is rotated to be the first polarization direction in accordance with the voltage applied to a pair of second electrodes (not shown). The second electrodes are similar to the first electrodes E of the first electro-optic element EO1 shown in FIGS. 2 and 5 and the like.

It is desirable that a second electro-optic element material included in the second electro-optic element EO2 be the same as the first electro-optic element material, but the present disclosure is not limited thereto. It may be possible to use materials such as DKDP having a lower internal transmittance for ultraviolet light as the second electro-optic element material when an amplifier of a subsequent stage has adequate amplifying performance.

The second drive power supply DR2 applies second voltage DV2 to the second electrodes. The second voltage DV2 is half-wavelength voltage of the second electro-optic element material.

The second polarizer P2 is disposed in an optical path of third seed light SB3a output from the second electro-optic element EO2.

The third amplifier AMP3 is disposed in an optical path of the third seed light SB3a having the first polarization direction output from the second polarizer P2. The third amplifier AMP3 amplifies the third seed light SB3a having the first polarization direction and outputs the first pulse laser beam B1 having the first polarization direction.

In the laser system 100e, the second laser light source LS2 includes a fourth amplifier AMP4. The fourth amplifier AMP4 is disposed in an optical path of the third seed light SB3a having the second polarization direction output from the second polarizer P2. The fourth amplifier AMP4 amplifies the third seed light SB3a having the second polarization direction and outputs the second pulse laser beam B2 having the second polarization direction. As above, the fourth amplifier AMP4 amplifies the third seed light SB3a having the second polarization direction output from the first laser light source LS1, and hence the second laser light source LS2 does not necessarily need to include the oscillator.

### 7.2 Operation

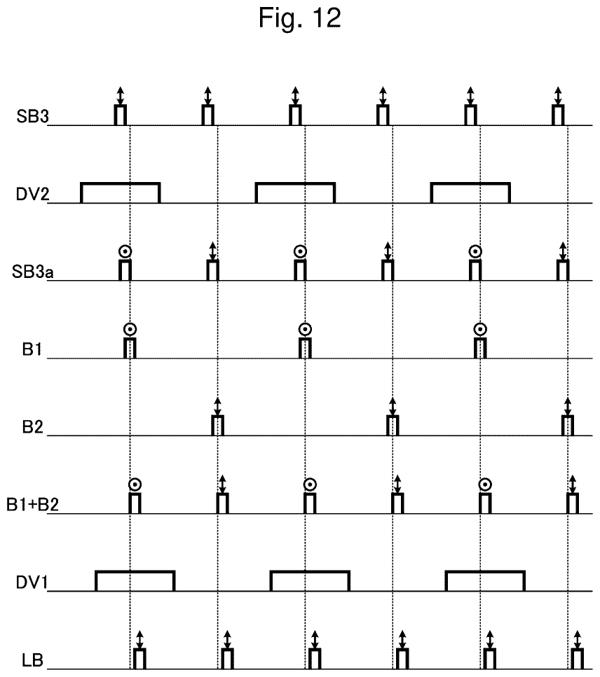

FIG. 12 is a timing chart of the fifth embodiment. Broken lines in the up-down direction in FIG. 12 indicate that events indicated in the positions of each broken line occur at the same time.

The processor PR sets the charging voltage of the fourth oscillator MO4 and controls the pulse energy of the third seed light SB3. The processor PR transmits a trigger signal to the fourth oscillator MO4 and controls the oscillation timing of the fourth oscillator MO4 such that the third seed light SB3 is output at the repetition frequency 2f. The repetition frequency 2f of the third seed light SB3 is 12 kHz, for example.

The processor PR controls the second drive power supply DR2 such that the second voltage DV2 is applied to the second electrodes at a timing at which an odd number pulse of a plurality of pulses included in the third seed light SB3 having the second polarization direction passes through the second electro-optic element EO2, for example. The second electro-optic element EO2 rotates the polarization direction of the third seed light SB3 by 90° and transmits the third seed light SB3 while the second voltage DV2 is applied to the second electrodes, and directly transmits the third seed light SB3 without changing the polarization direction of the third seed light while the second voltage DV2 is not applied to the second electrodes. Thus, the second electro-optic element EO2 outputs the third seed light SB3a in which pulses having the first polarization direction and pulses having the second polarization direction are alternately included.

The second polarizer P2 reflects the pulse having the first polarization direction and transmits the pulse having the second polarization direction out of the third seed light SB3a, to thereby split the third seed light SB3a and propagate the third seed light SB3a in separate directions. Each of the repetition frequency of the third seed light SB3a having the first polarization direction and the repetition frequency of the third seed light SB3a having the second polarization direction output from the second polarizer P2 is f that is half of the repetition frequency 2f and is 6 kHz, for example.

Here, a case in which the pulse having the first polarization direction out of the third seed light SB3a is S-polarized light with respect to the second polarizer P2 and the pulse having the second polarization direction out of the third seed light SB3a is P-polarized light with respect to the second polarizer P2 has been shown, but the relationship between the S-polarized light and the P-polarized light may be reversed. In other words, the second polarizer P2 may transmit a pulse having the first polarization direction and reflect a pulse having the second polarization direction out of the third seed light SB3a.

The processor PR sets the charging voltage of each of the third amplifier AMP3 and the fourth amplifier AMP4 and controls the pulse energy of the first pulse laser beam B1 and the second pulse laser beam B2. The processor PR transmits a trigger signal to each of the third amplifier AMP3 and the fourth amplifier AMP4 and controls the excitation timing such that the laser medium is excited at a timing at which each of the third seed light SB3a split by the second polarizer P2 is caused to enter the corresponding one of the third amplifier AMP3 and the fourth amplifier AMP4.

The operation after the first pulse laser beam B1 and the second pulse laser beam B2 enter the beam combiner COM is similar to that of the third embodiment.

Although a case in which the fourth oscillator MO4 outputs the third seed light SB3 having the second polarization direction has been described, the present disclosure is not limited thereto. The fourth oscillator MO4 may output the third seed light SB3 having the first polarization direction. In this case, the second electro-optic element EO2 rotates some pulses out of the pulses included in the third seed light SB3 to the second polarization direction.

### 7.3 Effects

According to the fifth embodiment, the first laser light source LS1 includes the fourth oscillator MO4, the second electro-optic element EO2, the second drive power supply DR2, the second polarizer P2, and the third amplifier AMP3. The fourth oscillator MO4 is configured to output the third seed light SB3 having the second polarization direction and having the wavelength λ of 183 nm or more and 300 nm or less. The second electro-optic element EO2 includes the second electro-optic element material that transmits the third seed light SB3, and the pair of second electrodes disposed on the second electro-optic element material. The second electro-optic element EO2 is configured to rotate the polarization direction of the third seed light SB3 to the first polarization direction in accordance with the voltage applied to the second electrodes. The second drive power supply DR2 is configured to apply, to the second electrodes, the second voltage DV2 that is half-wavelength voltage of the second electro-optic material. The second polarizer P2 is configured to reflect one of the third seed light SB3a having the first polarization direction that is transmitted through the second electro-optic element material and the third seed light SB3a having the second polarization direction that is transmitted through the second electro-optic element material, and transmit the other of the third seed light SB3a having the first polarization direction that is transmitted through the second electro-optic element material and the third seed light SB3a having the second polarization direction that is transmitted through the second electro-optic element material. The third amplifier AMP3 is configured to amplify the third seed light SB3a having the first polarization direction and output the first pulse laser beam B1. The second laser light source LS2 includes the fourth amplifier AMP4 configured to amplify the third seed light SB3a having the second polarization direction and output the second pulse laser beam B2.

According to the above configuration, only one oscillator is required, and hence the laser system 100e can be made compact. The wavelength control only needs to be performed by one oscillator, and hence the wavelength control can be facilitated.

Regarding other features, the fifth embodiment is similar to the third embodiment.

### 8. Other

### 8.1 Method of Manufacturing Electronic Device

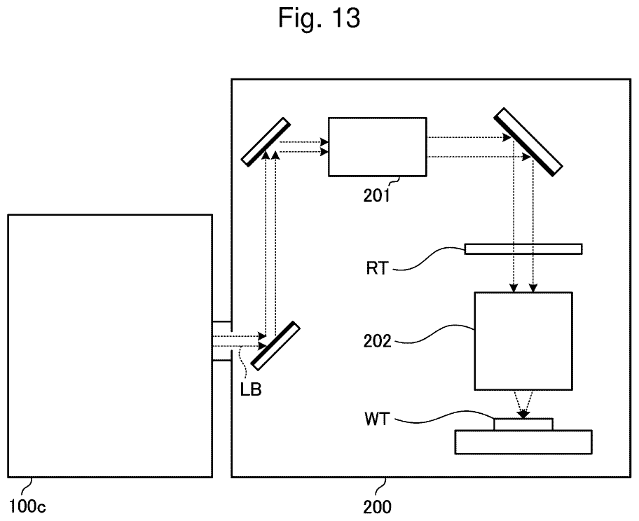

FIG. 13 shows a configuration of an exposure system. The exposure system includes the laser system 100c and the exposure apparatus 200. The laser system 100c is configured to output the laser beam LB including the first pulse laser beam B1 and the second pulse laser beam B2 toward the exposure apparatus 200. The propagation directions and the polarization directions of the first pulse laser beam B1 and the second pulse laser beam B2 are aligned. The laser system 100d or the laser system 100e may be used instead of the laser system 100c.

The exposure apparatus 200 includes an illumination optical system 201 and a projection optical system 202. The illumination optical system 201 illuminates a reticle pattern of a reticle (not shown) disposed on a reticle stage RT with the laser beam LB incoming from the laser system 100c. The projection optical system 202 performs reduced projection of the laser beam LB transmitted through the reticle and forms an image on a workpiece (not shown) disposed on a workpiece table WT. The workpiece is a photosensitive substrate such as a semiconductor wafer on which a photoresist has been applied.

The exposure apparatus 200 parallelly moves the reticle stage RT and the workpiece table WT in a synchronous manner, to thereby expose the workpiece to the laser beam LB in which the reticle pattern is reflected. The electronic device can be manufactured by undergoing a plurality of processes after the reticle pattern is transferred onto the semiconductor wafer by an exposure process as described above.

### 8.2 Supplementary

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the claims should be interpreted as non-limiting terms unless otherwise noted. For example, terms such as “comprise”, “include”, “have”, and “contain” should not be interpreted to be exclusive of components other than those described. Further, indefinite articles “a/an” 10 should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser apparatus, comprising:
a first laser light source configured to output a first pulse laser beam having a wavelength of 183 nm or more and 300 nm or less; and
a first electro-optic element including
a first electro-optic element material that includes either CLBO or LB4 and transmits the first pulse laser beam, and
a pair of first electrodes disposed on the first electro-optic element material.

2. The laser apparatus according to claim 1, wherein
the first electro-optic element material includes the CLBO,
a transmission direction of the first pulse laser beam and a direction of application of voltage by the first electrodes are both a c-axis direction of the CLBO, and
a length of the CLBO in the c-axis direction is 0.7 times or more and 1.0 times or less of a length of a long side of a surface of the CLBO on which the first pulse laser beam is incident.

3. The laser apparatus according to claim 2, wherein the length in the c-axis direction is 5 mm or more and 20 mm or less.

4. The laser apparatus according to claim 1, wherein
the first electro-optic element material includes the CLBO, and
the first electrodes each have a slit-shaped opening through which the first pulse laser beam passes.

5. The laser apparatus according to claim 1, wherein
the first electro-optic element material includes the LB4;
a transmission direction of the first pulse laser beam is perpendicular to a c-axis direction of the LB4,
a direction of application of voltage by the first electrodes is the c-axis direction, and
a length of the LB4 in the c-axis direction is 2 mm or more and 6 mm or less.

6. The laser apparatus according to claim 5, wherein a length of the LB4 in the transmission direction of the first pulse laser beam is 10 mm or more and 30 mm or less.

7. A laser system, comprising:
a first laser light source configured to output a first pulse laser beam that has a first polarization direction and has a wavelength of 183 nm or more and 300 nm or less;
a second laser light source configured to output a second pulse laser beam that has a second polarization direction orthogonal to the first polarization direction and has a wavelength of 183 nm or more and 300 nm or less;
a beam combiner including
a first polarizer configured to combine the first pulse laser beam and the second pulse laser beam and propagate the first pulse laser beam and the second pulse laser beam in a same direction by reflecting one of the first pulse laser beam and the second pulse laser beam and transmitting the other of the first pulse laser beam and the second pulse laser beam,
a first electro-optic element including
a first electro-optic element material that includes either CLBO or LB4 and transmits the first pulse laser beam and the second pulse laser beam, and
a pair of first electrodes disposed on the first electro-optic element material, and
a first drive power supply configured to apply, to the first electrodes, first voltage that is half-wavelength voltage of the first electro-optic element material; and
a processor configured to control the first laser light source and the second laser light source such that the first pulse laser beam and the second pulse laser beam are alternately output, and control the first drive power supply such that a polarization direction of one of the first pulse laser beam and the second pulse laser beam is rotated to be same as a polarization direction of the other of the first pulse laser beam and the second pulse laser beam.

8. The laser system according to claim 7, wherein
the first laser light source includes:
a first oscillator configured to output first seed light that has the first polarization direction and has a wavelength of 183 nm or more and 300 nm or less; and
a first amplifier configured to amplify the first seed light and output the first pulse laser beam, and
the second laser light source includes:
a second oscillator configured to output second seed light that has the second polarization direction and has a wavelength of 183 nm or more and 300 nm or less; and
a second amplifier configured to amplify the second seed light and output the second pulse laser beam.

9. The laser system according to claim 7, wherein
the first electro-optic element material includes the CLBO,
a transmission direction of the first pulse laser beam and a direction of application of voltage by the first electrodes are both a c-axis direction of the CLBO, and
a length of the CLBO in the c-axis direction is 0.7 times or more and 1.0 times or less of a length of a long side of a surface of the CLBO on which the first pulse laser beam is incident.

10. The laser system according to claim 9, wherein the length in the c-axis direction is 5 mm or more and 20 mm or less.

11. The laser system according to claim 7, wherein
the first electro-optic element material includes the CLBO, and
the first electrodes each have a slit-shaped opening through which the first pulse laser beam passes.

12. The laser system according to claim 7, wherein
the first electro-optic element material includes the LB4,
a transmission direction of the first pulse laser beam is perpendicular to a c-axis direction of the LB4,
a direction of application of voltage by the first electrodes is the c-axis direction, and
a length of the LB4 in the c-axis direction is 2 mm or more and 6 mm or less.

13. The laser system according to claim 12, wherein a length of the LB4 in a transmission direction of the first pulse laser beam is 10 mm or more and 30 mm or less.

14. The laser system according to claim 7, wherein
the first electro-optic element material includes the CLBO, and
the first voltage is 8 kV or more and 12 kV or less.

15. The laser system according to claim 7, wherein
the first electro-optic element material includes the LB4, and
the first voltage is 4 kV or more and 41 kV or less.

16. The laser system according to claim 7, wherein
the first electro-optic element material includes the LB4, and
the first voltage is 4 kV or more and 15 kV or less.

17. The laser system according to claim 7, wherein the first laser light source includes:
a third oscillator configured to output a third pulse laser beam having the second polarization direction and having a wavelength of 183 nm or more and 300 nm or less; and
a polarization rotation element configured to rotate a polarization direction of the third pulse laser beam to make the third pulse laser beam the first pulse laser beam having the first polarization direction.

18. The laser system according to claim 7, wherein
the first laser light source includes:
a fourth oscillator configured to output third seed light that has the second polarization direction and has a wavelength of 183 nm or more and 300 nm or less;
a second electro-optic element including a second electro-optic element material that transmits the third seed light, and a pair of second electrodes disposed on the second electro-optic element material, the second electro-optic element being configured to rotate a polarization direction of the third seed light to the first polarization direction in accordance with voltage applied to the second electrodes;
a second drive power supply configured to apply, to the second electrodes, second voltage that is half-wavelength voltage of the second electro-optic element material;
a second polarizer configured to reflect one of the third seed light having the first polarization direction that is transmitted through the second electro-optic element material and the third seed light having the second polarization direction that is transmitted through the second electro-optic element material, and transmit the other of the third seed light having the first polarization direction that is transmitted through the second electro-optic element material and the third seed light having the second polarization direction that is transmitted through the second electro-optic element material; and
a third amplifier configured to amplify the third seed light having the first polarization direction and output the first pulse laser beam, and
the second laser light source includes a fourth amplifier configured to amplify the third seed light having the second polarization direction and output the second pulse laser beam.

19. The laser system according to claim 7, wherein
the first laser light source includes:
a fourth oscillator configured to output third seed light that has the first polarization direction and has a wavelength of 183 nm or more and 300 nm or less;
a second electro-optic element including a second electro-optic element material that transmits the third seed light, and a pair of second electrodes disposed on the second electro-optic element material, the second electro-optic element being configured to rotate a polarization direction of the third seed light to the second polarization direction in accordance with voltage applied to the second electrodes;
a second drive power supply configured to apply, to the second electrodes, second voltage that is half-wavelength voltage of the second electro-optic element material;
a second polarizer configured to reflect one of the third seed light having the first polarization direction that is transmitted through the second electro-optic element material and the third seed light having the second polarization direction that is transmitted through the second electro-optic element material, and transmit the other of the third seed light having the first polarization direction that is transmitted through the second electro-optic element material and the third seed light having the second polarization direction that is transmitted through the second electro-optic element material; and
a third amplifier configured to amplify the third seed light having the first polarization direction and output the first pulse laser beam, and
the second laser light source includes a fourth amplifier configured to amplify the third seed light having the second polarization direction and output the second pulse laser beam.

20. A method of manufacturing an electronic device, the method comprising:
generating, with a laser system, a first pulse laser beam that has a first polarization direction and has a wavelength of 183 nm or more and 300 nm or less and a second pulse laser beam that has a second polarization direction orthogonal to the first polarization direction and has a wavelength of 183 nm or more and 300 nm or less, the laser system including
a first laser light source configured to output the first pulse laser beam,
a second laser light source configured to output the second pulse laser beam,
a beam combiner including
a first polarizer configured to combine the first pulse laser beam and the second pulse laser beam and propagate the first pulse laser beam and the second pulse laser beam in a same direction by reflecting one of the first pulse laser beam and the second pulse laser beam and transmitting the other of the first pulse laser beam and the second pulse laser beam,
a first electro-optic element including
a first electro-optic element material that includes either CLBO or LB4 and transmits the first pulse laser beam and the second pulse laser beam, and
a pair of first electrodes disposed on the first electro-optic element material, and
a first drive power supply configured to apply, to the first electrodes, first voltage that is half-wavelength voltage of the first electro-optic element material, and
a processor configured to control the first laser light source and the second laser light source such that the first pulse laser beam and the second pulse laser beam are alternately output, and control the first drive power supply such that a polarization direction of one of the first pulse laser beam and the second pulse laser beam is rotated to be same as a polarization direction of the other of the first pulse laser beam and the second pulse laser beam;
outputting the first pulse laser beam and the second pulse laser beam to an exposure apparatus; and
exposing a photosensitive substrate to the first pulse laser beam and the second pulse laser beam within the exposure apparatus to manufacture the electronic device.
